(19) United States
(12) Patent Application Publication
(10) Pub. No.: US 2026/0305146 A1
(43) Pub. Date: Oct. 1, 2026

(54) DISPLAY PANEL AND DISPLAY DEVICE

(71) Applicant: Wuhan Tianma Microelectronics Co., Ltd., Wuhan (CN)

(72) Inventor: Wanqiu Zhang, Wuhan (CN)

(73) Assignee: Wuhan Tianma Microelectronics Co., Ltd., Wuhan (CN)

(21) Appl. No.: 19/576,569

(22) Filed: Mar. 24, 2026

(30) Foreign Application Priority Data
Nov. 5, 2025 (CN) 202511614089.5

(51) Int. Cl. H10K 59/80; H10H 29/34; H10H 29/855; H10K 59/35

(52) U.S. Cl. CPC H10K 59/8792; H10H 29/345; H10H 29/855; H10H 29/8552; H10K 59/352; H10K 59/877; H10K 59/879

(57) ABSTRACT

Provided are a display panel and a display device. A light-emitting layer includes a first light-emitting unit, a width of which in a first direction is less than that in a second direction; a shielding layer is located at a side of the light-emitting layer facing the light-emitting surface of the display panel and includes a light-shielding structure located at a periphery of the light-emitting unit; the light control layer is located at a side of the shielding layer away from the light-emitting layer and includes a first light control unit overlapping the first light-emitting unit in a direction perpendicular to a plane of the display panel; and the first light control unit includes a first light-diffusing structure and/or a first light-converging structure. The picture displayed by the display panel has no obvious color difference under the wide viewing angle in each direction.

### CROSS-REFERENCE TO RELATED DISCLOSURE

The present disclosure claims priority to Chinese Patent Application No. 202511614089.5, filed on Nov. 11, 2025, the content of which is incorporated herein by reference in its entirety.

### TECHNICAL FIELD

The present disclosure relates to the field of display technologies, and in particular, to a display panel and a display device.

### BACKGROUND

With the development of display technologies, pixels in the display panels present more and more diversified shapes For example, in a real arrangement manner of pixels in an OLED display panel with a medium size, a part of pixels generally exhibit a rectangle, and a difference between a length and a width of the part of pixels is relatively large. When a structure with a light-shielding effect is arranged above the OLED light-emitting layer, color shift at a large angle easily occurs at some viewing angles, and thus obvious differences in horizontal and vertical viewing effects will occur. Therefore, when a difference between a length and a width of a part of pixels in the display panel is large, color shift at a certain angle may occur.

### SUMMARY

Embodiments of the present disclosure provide a display panel and a display device to solve the above problems.

In a first aspect, an embodiment of the present disclosure provides a display panel, including: a light-emitting layer, a shielding layer and a light control layer.

The light-emitting layer includes a plurality of light-emitting units, the plurality of light-emitting units include a first light-emitting unit, a width of the first light-emitting unit along a first direction is less than a width of the first light-emitting unit along a second direction, the first direction intersects with the second direction, and both the first direction and the second direction are parallel to a plane of the display panel.

The shielding layer is located at a side of the light-emitting layer facing the light-emitting surface of the display panel, the shielding layer includes a light-shielding structure, and the light-shielding structure is located at a periphery of the light-emitting unit.

The light control layer is located on a side of the shielding layer away from the light-emitting layer, and the light control layer includes a plurality of light control units.

The plurality of light control units include a first light control unit, the first light control unit is overlapped with the first light-emitting unit in a direction perpendicular to the plane of the display panel, the first light control unit includes a first light-diffusing structure and/or a first light-converging structure, the first light-diffusing structure extends along the second direction, and the first light-converging structure extends along the first direction.

In a second aspect, an embodiment of the present disclosure provides a display device including the display panel according to the first aspect.

According to the technical solutions provided by the embodiments of the present disclosure, the light control units above the light-emitting unit modulate the light with unbalanced light amount in all directions, so that the picture displayed by the display panel has no obvious color difference under a wide viewing angle in all directions, and the display panel can accurately express the color of the picture under the wide viewing angle in each direction, thereby improving the user experience.

### BRIEF DESCRIPTION OF DRAWINGS

In order to more clearly describe the technical solutions of the embodiments of the present disclosure, the following briefly describes the accompanying drawings that need to be used in the embodiments. Obviously, the accompanying drawings described below are merely some embodiments of the present disclosure, and for those skilled in the art, other accompanying drawings may be obtained based on these accompanying drawings without any creative effort.

FIG. 1 is a schematic diagram of a display panel according to an embodiment of the present disclosure.

FIG. 2 is a schematic cross-sectional diagram corresponding to FIG. 1.

FIG. 3 is a schematic diagram of light transmission with respect to an embodiment of the present disclosure.

FIG. 4 is a schematic diagram of a projection of a first light-emitting unit.

FIG. 5 is a schematic diagram of a projection of a first light-emitting unit.

FIG. 6 is a schematic diagram showing the light transmission of the light emitted by a first light-emitting unit.

FIG. 7 is a schematic cross-sectional diagram of a first light-emitting unit along a first direction.

FIG. 8 is a schematic cross-sectional diagram of a first light-emitting unit along a second direction.

FIG. 9 is a schematic cross-sectional diagram of a first light-emitting unit along a second direction.

FIG. 10 is a schematic cross-sectional diagram of a first light-emitting unit along a first direction.

FIG. 11 is a schematic cross-sectional diagram of a first light-emitting unit along a first direction.

FIG. 12 is a schematic cross-sectional diagram of a first light-emitting unit along a first direction.

FIG. 13 is a schematic cross-sectional diagram of a second light-emitting unit along a second direction.

FIG. 14 is a schematic cross-sectional diagram of a second light-emitting unit along a second direction.

FIG. 15 is a schematic cross-sectional diagram of a second light-emitting unit along a second direction.

FIG. 16 is a schematic diagram of a projection of a first light-emitting unit.

FIG. 17 is a schematic diagram of a projection of a first light-emitting unit.

FIG. 18 is a schematic diagram of a projection of a third light-emitting unit.

FIG. 19 is a schematic diagram of a projection of a third light-emitting unit.

FIG. 20 is a schematic diagram of a projection of a third light-emitting unit.

FIG. 21a is a schematic cross-sectional diagram of a first light-emitting unit along a second direction.

FIG. 21b is a schematic cross-sectional diagram of a first light-emitting unit along a first direction.

FIG. 22a is a schematic cross-sectional diagram of a first light-emitting unit along a second direction;

FIG. 22b is a schematic cross-sectional diagram of a first light-emitting unit along a first direction.

FIG. 23a is a schematic cross-sectional diagram of a first light-emitting unit along a second direction.

FIG. 23b is a schematic cross-sectional diagram of a first light-emitting unit along a first direction.

FIG. 24 is a schematic diagram of a display panel according to an embodiment of the present disclosure.

FIG. 25 a schematic diagram of a display panel according to an embodiment of the present disclosure.

FIG. 26 is a schematic diagram of a display device according to an embodiment of the present disclosure.

### DESCRIPTION OF EMBODIMENTS

In order to better understand the technical solutions of the present disclosure, embodiments of the present disclosure are described in detail below in conjunction with the drawings.

It should be clear that the described embodiments are merely some, rather than all, of the embodiments of the present disclosure. All other embodiments obtained by those skilled in the art without any creative efforts based on embodiments of the present disclosure shall fall within the protection scope of the present disclosure.

Terms used in the embodiments of the present disclosure are merely for the purpose of describing specific embodiments and are not intended to limit the present disclosure. The singular forms “a” and “the” used in the embodiments of the present disclosure and the appended claims are also intended to include plural forms unless the context clearly indicates other meanings.

It should be understood that the term “and/or” used herein is merely an association relationship describing an associated object, and indicates that there may be three relationships. For example, A and/or B may indicate: A alone, both A and B, and B alone. In addition, the character “/” herein generally indicates that the associated objects prior to and subsequent to the character are in an “or” relationship.

In the description of the present disclosure, it should be understood that the terms such as “substantially”, “approximate to”, “approximately”, “about”, “roughly”, and “in general” described in the claims and embodiments of the present disclosure donate a generally acceptable approximation within a reasonable process operation range or tolerance range, rather than an exact value.

It should be understood that although the terms “first”, “second” and the like may be used in the embodiments of the present disclosure to describe the light-emitting units, the light control units and the like, these should not be limited to these terms. These terms are only used to distinguish light-emitting units, light control units and the like from each other. For example, without departing from the scope of the embodiments of the present disclosure, the first light-emitting unit may also be referred to as a second light-emitting unit, and similarly, the second light-emitting unit may also be referred to as a first light-emitting unit. Through careful and in-depth research, the applicant provides solutions to the problems existing in the related art.

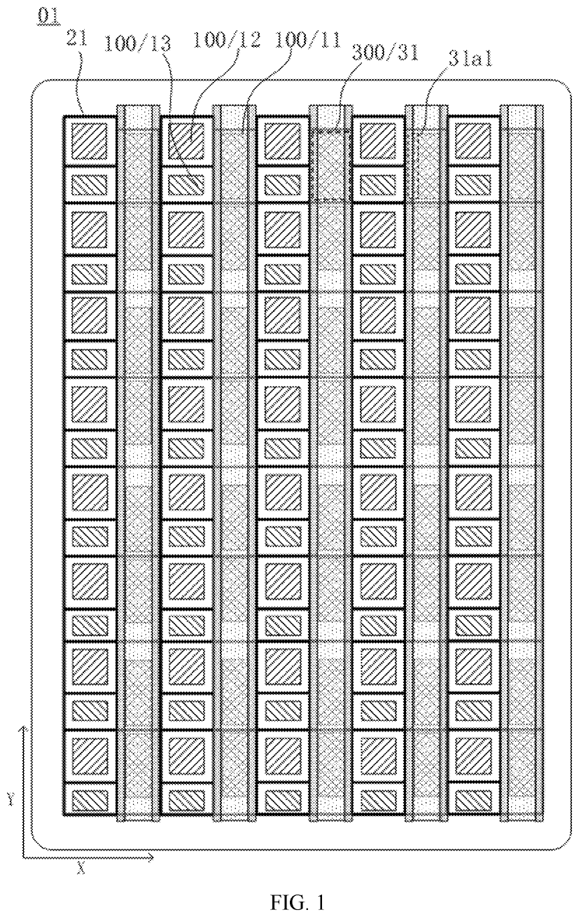

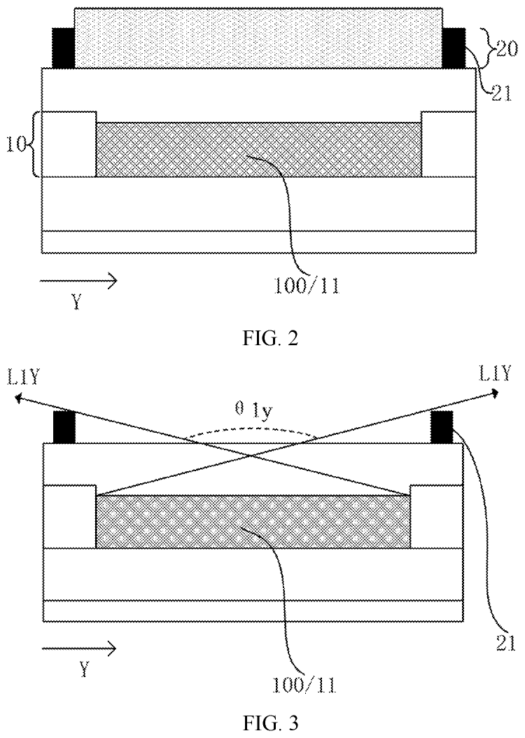

FIG. 1 is a schematic diagram of a display panel according to an embodiment of the present disclosure. FIG. 2 is a schematic cross-sectional diagram corresponding to FIG. 1. FIG. 2 includes a schematic cross-sectional diagram of a first light-emitting unit 11 along a first direction X and a schematic cross-sectional diagram of a first light-emitting unit 11 along a second direction Y.

With reference to FIG. 1 and FIG. 2, the display panel 01 provided by an embodiment of the present disclosure includes a light-emitting layer 10, a shielding layer and a light control layer 30. The shielding layer may be located at the side of the light-emitting layer 10 facing the light-emitting surface of the display panel 01, and the light control layer 30 may be located at the side of the shielding layer away from the light-emitting layer 10.

In some embodiments, the light-emitting layer 10 includes a plurality of light-emitting units 100. The light-emitting unit 100 may be at least one of an organic light-emitting diode (OLED), a micro light-emitting diode (Micro-LED), and a submillimeter light-emitting diode (Mini-LED).

In some embodiments, the shielding layer includes a light-shielding structure 21 located at a periphery of the light-emitting unit 100. It should be noted that the light-shielding structure 21 and the light-emitting unit 100 are not in the same layer, and that the expression “the light-shielding structure 21 [is] located at a periphery of the light-emitting unit 100” means that a region where the light-shielding structure 21 is located is located at a periphery of a region where the light-emitting unit 100 is located. Therefore, an orthographic projection of the light-shielding structure 21 on the light-emitting layer 10 is located at a periphery of the light-emitting unit 100. The light-shielding structure 21 can block the light emitted by the light-emitting unit 100 located at one side of the light-shielding structure 21 from being emitted to the region where the light-emitting unit 100 located at the other side of the light-shielding structure 21 is located, thereby avoiding light crosstalk of the pixels where adjacent light-emitting units 100 are located. The light-shielding structure 21 may be a black matrix or, alternatively, a conductive structure. For example, the light-shielding structure 21 may be a metal wire included in a metal mesh touch electrode.

With continued reference to FIG. 1 and FIG. 2, the plurality of light-emitting units 100 may include a first light-emitting unit 11. In some embodiments, a width of the first light-emitting unit 11 along the first direction X is less than a width of the first light-emitting unit 11 along the second direction Y. The first direction X intersects with the second direction Y, and both the first direction X and the second direction Y are parallel to a plane of the display panel 01. The first direction X may be perpendicular to the second direction Y, and both the first direction X and the second direction Y may be perpendicular to a thickness direction of the display panel 01. For example, the first direction X may be parallel to a transverse direction in the plane of the display panel 01, and the second direction Y may be parallel to a longitudinal direction in the plane of the display panel 01. Since the light-shielding structure 21 is located at the periphery of the light-emitting unit 100, in the light-shielding structure 21 at the periphery of the first light-emitting unit 11, a length of a portion extending along the first direction X is shorter than a length of a portion extending along the second direction Y.

FIG. 3 is a schematic diagram of light transmission related to an embodiment of the present disclosure. FIG. 3 includes a schematic cross-sectional diagram of a first light-emitting unit 11 in the prior art along a first direction X and a schematic cross-sectional diagram of a first light-emitting unit 11 along a second direction Y.

According to the exemplary embodiment shown in FIG. 3, constrained by space, a distance between an edge of the light-shielding structure 21 and an edge of the light-emitting unit 100 in the first direction X is just slightly different from, or is substantially the same as a distance between the edge of the light-shielding structure 21 and the edge of the light-emitting unit 100 in the second direction Y. Since the width of the first light-emitting unit 11 in the second direction Y is greater, as shown in FIG. 3, more light at large angles can be seen at a wide viewing angle at the side of the first light-emitting unit 11 in the second direction Y, and less light can be seen at a wide viewing angle at the side of the first light-emitting unit 11 in the first direction X. In addition, a length of a portion of the light-shielding structure 21 extending along the second direction Y at a periphery of the first light-emitting unit 11 is greater than a length of a portion of the light-shielding structure 21 extending along the first direction X. That is, the light-shielding structure 21 located outside the first light-emitting unit 11 in the first direction X has a greater a length and the light-shielding structure 21 located outside the first light-emitting unit 11 in the second direction Y has a shorter length. Therefore, the occlusion ration of the light-shielding structure 21 to the light emitted by the first light-emitting unit 11 in the first direction X is greater than the occlusion ration of the light-shielding structure 21 to the light emitted by the first light-emitting unit 11 in the second direction Y.

An example in which the light emitted by the first light-emitting unit 11 is the first color light is used for description. For the above reasons, a light amount of the first color light L1Y seen at a wide viewing angle in the second direction Y is greater than a light amount of the first color light L1X seen at a wide viewing angle in the first direction X. For example, an angle range in which the first color light L1X can be seen in the first direction X is θ1x, an angle range in which the first color light L1Y can be seen in the second direction Y is θ1y, and θ1y>θ1x. When the screen is viewed at a viewing angle greater than 0.5*θ1x, the first color light can be seen at a wide viewing angle in the first direction X, and the first color light cannot be basically seen at a wide viewing angle in the second direction Y. When the light of the first color is mixed with the light emitted by the light-emitting units 100 of other colors, the color of the picture seen at a wide viewing angle in the second direction Y is different from the color of the picture seen at a wide viewing angle in the first direction X. Assuming that the light of the first color is blue light, the picture seen at a wide viewing angle in the first direction X tends towards yellow, and/or the picture seen at a wide viewing angle in the second direction Y tends towards blue.

In order to solve the above problems, as shown in FIG. 1 and FIG. 2, some embodiments of the present disclosure further provide a light control layer 30 located at a side of the shielding layer away from the light-emitting layer 10. That is, the light control layer 30 is located at a side of the shielding layer facing a light-emitting surface of the display panel 01, so that the light control layer 30 can regulate the light emitted by the light-emitting unit 100. The light control layer 30 may include a plurality of light control units 300, which may be overlapped with the light-emitting units 100 in the direction perpendicular to the plane of the display panel 01, so as to regulate an optical path of the light emitted by the light-emitting unit 100 overlapped with the light control unit 300.

In some embodiments, the plurality of light control units 300 include a first light control unit 31, and the first light control unit 31 is overlapped with the first light-emitting unit 11 in the direction perpendicular to the plane of the display panel 01. That is. That is, the first light control unit 31 is configured to regulate an optical path of the light that is emitted by the first light-emitting unit 11 and passes through the shielding layer, to solve the above problem.

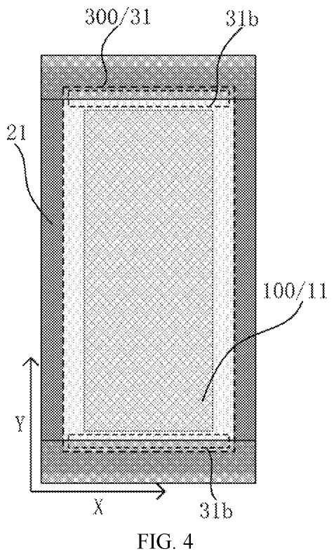

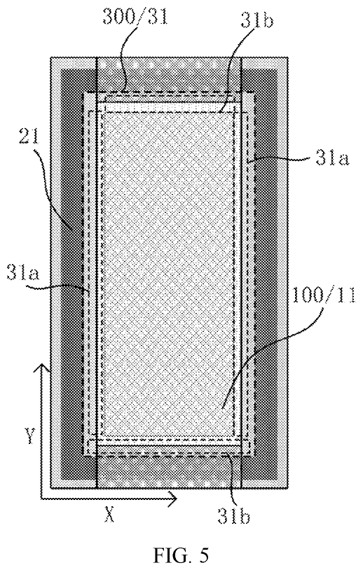

FIG. 4 is a schematic diagram of a projection of a first light-emitting unit. FIG. 5 is a schematic diagram of a projection of a first light-emitting unit.

According to the exemplary embodiments shown in FIGS. 1 to 2 and 4 to 5, the first light control unit 31 includes a first light-diffusing structure 31a and/or a first light-converging structure 31b. The light-diffusing structure can scatter the light received by the light-diffusing structure, so that the overall emergent angle of the light received by the light-diffusing structure increases. That is the maximum angle of the light emitted by the light-diffusing structure is greater than the maximum angle of the light received by the light-diffusing structure. The light-converging structure can converge the light received by the light-converging structure, so that the overall emergent angle of the light received by the light-converging structure decreases. That is, the maximum angle of the light emitted by the light convergence structure is less than the maximum angle of the light received by the light-converging structure.

In some embodiments, the first light-diffusing structure 31a extends along the second direction Y. That is, an edge of the first light-emitting unit 11 extending along the second direction Y is substantially parallel to the first light-diffusing structure 31a. In other words, an edge of the first light-emitting unit 11 arranged along the first direction X is substantially parallel to the first light-diffusing structure 31a. The first light-diffusing structure 31a may scatter light emitted from the first light-emitting unit 11 towards a first viewing angle, which is a viewing angle located at a side of a region where the first light-emitting unit 11 is located in the first direction X. When the first light control unit 31 includes the first light-diffusing structure 31a, the viewing angle range of the first color light that can be seen by the viewing angle located at a side of the first light-emitting unit 11 in the first direction X is expanded.

In some embodiments, the first light-converging structure 31b extends along the first direction X That is, an edge of the first light-emitting unit 11 extending along the first direction X is substantially parallel to the first light-converging structure 31b. In other words, an edge of the first light-emitting unit 11 arranged along the second direction Y is substantially parallel to the first light-converging structure 31b. The first light-converging structure 31b may converge light emitted by the first light-emitting unit 11 facing a second viewing angle which is a viewing angle located at a side of a region where the first light-emitting unit 11 is located in the second direction Y. When the first light control unit 31 includes the first light-converging structure 31b, the viewing angle range of the first color light that can be seen by the viewing angle located at the side of the first light-emitting unit 11 in the first direction X is reduced.

In some embodiments, such as the exemplary embodiments shown in FIG. 1 and FIG. 2, the first light control unit 31 includes only the first light-diffusing structure 31a. In this case, by expanding the viewing angle range in which the first color light can be seen at the side of the first light-emitting unit 11 in the first direction X, the light amounts at a wide viewing angle in the first direction X wide viewing angle and in the second direction Y are balanced. Moreover, by increasing the light amount of the first color at a first viewing angle, color shift at a first viewing angle can be reduced, and the brightness of the display panel 01 at a wide viewing angle can be improved.

In some embodiments, such as the exemplary embodiment shown in FIG. 4, the first light control unit 31 includes only the first light-converging structure 31b. In this way, by reducing the viewing angle range in which the first color light can be seen at the side of the first light-emitting unit 11 in the second direction Y, the light amounts at a wide viewing angle in the second direction Y wide viewing angle and in the first direction Y are balanced.

In some embodiments, such as the exemplary embodiment shown in FIG. 5, the first light control unit 31 includes both the first light-diffusing structure 31a and the first light-converging structure 31b. In this way, by simultaneously expanding the viewing angle range in which the first color light can be seen at the side of the first light-emitting unit 11 in the first direction X and reducing the viewing angle range in which the first color light can be seen on the side of the first light-emitting unit 11 in the second direction Y, the light amounts at a wide viewing angle in the first direction X wide viewing angle and in the second direction Y are balanced.

In some embodiments, the light control unit 300 is provided at a side of at least a part of the light-emitting units 100 facing the light-emitting surface of the display panel 01. The light control layer 30 including the light control unit 300 is located at a side of the shielding layer away from the light-emitting layer 10, so that after light emitted by the light control unit 300 in different directions is shielded by the light-shielding structure 21 in the shielding layer, which causes attenuation in different degrees. The light control unit 300 located above the light-emitting unit 100 modulates light in a specific direction, so that a picture displayed by the display panel 01 does not have an obvious color difference between a wide viewing angle in the first direction X and a wide viewing angle in the second direction Y. The display panel 01 can accurately express a color of the picture at a wide viewing angle, thereby improving user experience.

In some embodiments, such as the exemplary embodiment shown in FIG. 2, the light control unit 300 includes a first structure 301 and a second structure 302, and a refractive index of the first structure 301 is greater than a refractive index of the second structure 302. The first structure 301 includes a first groove portion 3010, and at least part of the second structure 302 is filled in the first groove portion 3010. The first groove portion 3010 may be a hollow portion that penetrates through the first structure 301 (as shown in FIG. 2), or it may be a recessed structure that fails to penetrate through the first structure 301 and has an opening direction away from the light-emitting layer 10.

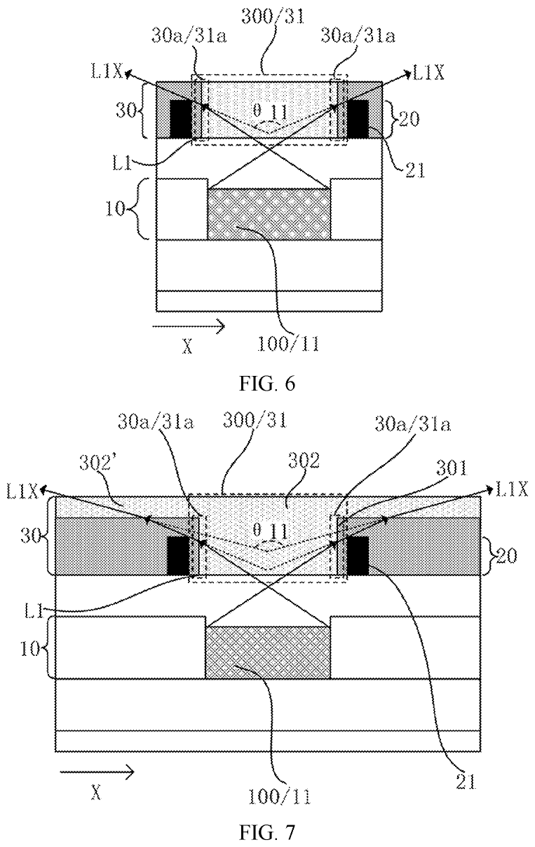

FIG. 6 is a light transmission diagram of light emitted by a first light-emitting unit.

With reference to the exemplary embodiments shown in FIG. 2 and FIG. 6, a side wall of the first groove portion 3010 is in contact with the second structure 302. After at least part of the light at large angles emitted by the light-emitting unit 100 reaches the light control layer 30, it undergoes a process of emitting from the second structure 302 with a lower refractive index to the first structure 301 with a higher refractive index. Since a normal direction of the side wall of the first groove portion 3010 is non-parallel to the direction perpendicular to the plane of the display panel 01, the angles of these light at large angles increase during this process, and therefore the area near the interface at the side walls of the first groove portion 3010 is regarded as the light-diffusing structure 30a.

In some embodiments, the first groove portion 3010 is overlapped with the light-emitting unit 100 in the direction perpendicular to the plane of the display panel 01. That is, the light control unit 300 is overlapped with the light-emitting unit 100 in the direction perpendicular to the plane of the display panel 01. Therefore, in an orthographic projection in the direction perpendicular to the plane of the display panel 01, an orthographic projection of the light-diffusing structure 30a may be overlapped with or be adjacent to an orthographic projection of an edge of the light-emitting unit 100.

With continued reference to FIG. 2 and FIG. 6, an example in which the first light control unit 31 above the first light-emitting unit 11 is used for description. The first color light emitted by the first light-emitting unit 11 at a large angle in the first direction X passes through the second structure 302 having a relatively low refractive index in the first groove portion 3010 and then passes through the side wall of the first groove portion 3010 to reach the first structure 301 having a relatively higher refractive index. That is, the first color light L1X emitted by the first light-emitting unit 11 at a large angle in the first direction X passes through the first light-diffusing structure 31a, and the propagation angle of the first color light L1X after passing through the first light-diffusing structure 31a is expanded.

FIG. 7 is a schematic cross-sectional diagram of a first light-emitting unit along a first direction.

In some embodiments, the film layer where the second structure 302 is located may further include an extension portion 302′ of the second structure 302. The second structure 302 and the extension portion 302′ thereof are different portions of the same film layer. The second structure 302 and the extension portion 302′ of the second structure 302 may be integrated with each other and may cover the first structure 301 together. As a result, the light emitted by the light-emitting unit 100 may pass through the light-diffusing structure 30a; then may be incident onto the extension portion 302′ of the second structure 302 with a relatively low refractive index again; and finally may be emitted from the extension portion 302′. Since the normal line of the interface between the extension portion 302′ of the second structure 302 and the film layer where the first structure 301 is located is substantially perpendicular to the direction of the plane of the display panel 01, the angle of the light at large angles passing through the extension portion 302′ is further expanded, and the angle of the light at large angles emitted by the light-emitting unit 100 at the viewing angle towards the first direction X viewing is further expanded.

For example, as shown in FIG. 3, the maximum viewing angle range of the first color light L1X can be seen at the viewing angle in the first direction X is θ1x. Even if a part of the first color light L1X is shielded by the light-shielding structure 21, because the width of the first light-emitting unit 11 along the second direction Y is greater than the width of the first light-emitting unit 11 along the first direction X, the maximum viewing angle range of the first color light L1X can be seen at the viewing angle in the second direction Y is θ1y, and θ1y is greater than θ1x. According to the embodiments shown in FIG. 6 and FIG. 7, the first light-diffusing structures 31a overlapped with or adjacent to edges, opposite to each other in the first direction X, of the first light-emitting unit 11 are provided above the first light-emitting unit 11, so that the emergent angle of the first color light L1X in the first direction X can diverge. Therefore, the maximum viewing angle range of the first color light can be seen at a viewing angle in the first direction X is θ11, θ11>θ1x, and θ11 may be substantially equal to θ12 by adjusting the first light-diffusing structures 31a.

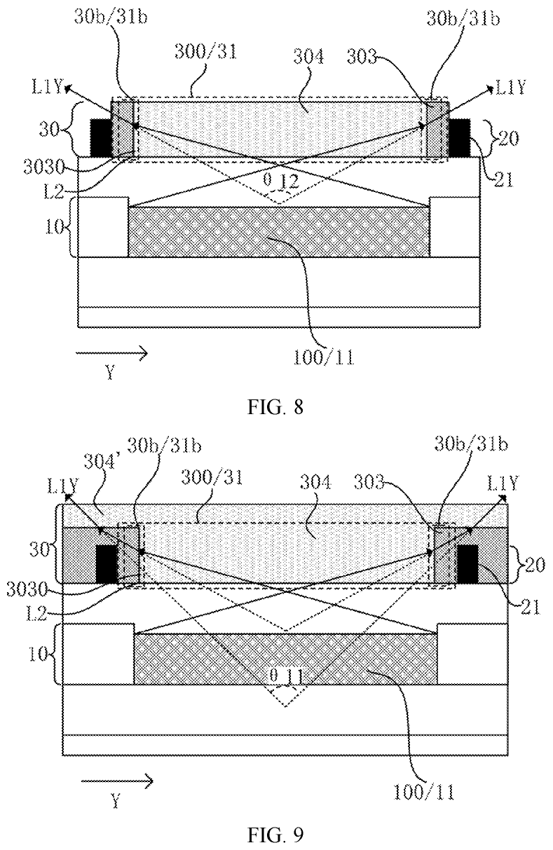

FIG. 8 is a schematic cross-sectional diagram of a first light-emitting unit along a second direction.

In some embodiments, such as the exemplary embodiment shown in FIG. 8, the light control unit 300 includes a third structure 303 and a fourth structure 304, and a refractive index of the third structure 303 is less than a refractive index of the fourth structure 304. The third structure 303 includes a second groove portion 3030, and at least part of the fourth structure 304 is filled in the second groove portion 3030. The second groove portion 3030 may be a hollow portion that penetrates through the third structure 303, as shown in FIG. 8, or it may be a recessed structure that fails to penetrate through the third structure 303 and has an opening direction away from the light-emitting layer 10.

In some embodiments, a side wall of the second groove portion 3030 is in contact with the fourth structure 304. After at least part of the light at large angles emitted by the light-emitting unit 100 reaches the light control layer 30, it will undergo the process of emitting from the fourth structure 304 with a higher refractive index to the third structure 303 with a lower refractive index. Since the normal direction of the side wall of the second groove portion 3030 is not parallel to the direction perpendicular to the plane of the display panel 01, the angles of the light at large angles will decrease in this process. Accordingly, the area adjacent to the interface at the side wall of the second groove portion 3030 can be regarded as the light-converging structure 30b.

In some embodiments, the second groove portion 3030 is overlapped with the light-emitting unit 100 in the direction perpendicular to the plane of the display panel 01. That is, the light control unit 300 is overlapped with the light-emitting unit 100 in the direction perpendicular to the plane of the display panel 01. Therefore, when an orthographically projected in the direction perpendicular to the plane of the display panel 01, an orthographic projection of the light-converging structure 30b may overlap or be adjacent to an orthographic projection of an edge of the light-emitting unit 100.

In some embodiments, such as the exemplary embodiment shown in FIG. 8, taking the first light control unit 31 above the first light-emitting unit 11 as an example, the first color light emitted by the first light-emitting unit 11 at a wide viewing angle in the second direction Y passes through the fourth structure 304 having a higher refractive index in the second groove portion 3030 and then passes through the side wall of the second groove portion 3030 to reach the third structure 303 having a lower refractive index. That is, the first color light L1Y emitted by the first light-emitting unit 11 at a large angle in the second direction Y passes through the first light-converging structure 31b, and the propagation angle of the first color light L1Y after passing through the first light-converging structure 31b is reduced.

FIG. 9 is a schematic cross-sectional diagram of a first light-emitting unit along a second direction.

In some embodiments, such as the exemplary embodiment shown in FIG. 9, the film layer where the fourth structure 304 is located may further include an extension portion 304′ of the fourth structure 304. The fourth structure 304 and the extension portion 304′ are different portions of the same film layer. The fourth structure 304 and the extension portion 304′ of the fourth structure 304 may be integrated with each other and may cover the third structure 303 together. Then, the light emitted by the light-emitting unit 100 may also be incident on the extension portion 304′ of the fourth structure 304 with a higher refractive index after passing through the light-converging structure 30b and be emitted from the extension portion 304′. Since the normal line of the interface between the extension portion 304′ of the fourth structure 304 and the film layer where the third structure 303 is located is substantially perpendicular to the direction of the plane of the display panel 01, the angle of the light at large angles passing through the extension portion 304′ is further reduced, and the angle of the light at large angles emitted by the light-emitting unit 100 facing the second direction Y is further reduced.

For example, as shown in FIG. 3, the maximum viewing angle range of the first color light L1Y can be seen at a viewing angle in the second direction Y is θ1y. Even if a part of the first color light L1Y is shielded by the light-shielding structure 21, since the width of the first light-emitting unit 11 along the first direction X is less than the width of the first light-emitting unit 11 along the second direction Y, the maximum viewing angle range of the first color light L1Y can be seen at a viewing angle in the first direction X is θ1x, and θ1x is less than θ1y. As shown in FIG. 8 and FIG. 9, the first light-converging structures 31b overlapped with or adjacent to edges, opposite to each other in the second direction Y, of the first light-emitting unit 11 are provided above the first light-emitting unit 11, so that the emergent angle of the first color light L1Y in the second direction Y can diverge. Therefore, the maximum viewing angle range of the first color light can be seen at a viewing angle in the second direction Y is θ12, and θ12>θ1y. Further, and θ12 may be substantially equal to θ11 by adjusting the first light-converging structure 31b.

In some embodiments, the second structure 302 and the fourth structure 304 may be identical to each other, and a portion of the first light-diffusing structure 31a located in the first groove portion 3010 and a portion of the first light-converging structure 31b located in the second groove portion 3030 are the same structure. Therefore, the structure of the film layer above the first light-emitting unit 11 is relatively simple, which reduces the light loss and minimizes the transmission abnormality of the first color light. In this case, the first structure 301 and the third structure 303 are structures with different refractive indexes, so as to form a light-diffusing structure and a light-converging structure with the second structure 302/the fourth structure 304, respectively.

In some embodiments, the first structure 301 and the third structure 303 are identical to each other, and the first groove portion 3010 in the first light-diffusing structure 31a and the second groove portion 3030 in the first light-converging structure 31b are the same groove portion. Therefore, the groove portion in the first light-diffusing structure 31a and the groove portion in the first light-converging structure 31b may be prepared simultaneously, thereby reducing the process difficulty.

In some embodiments, the first light control unit 31 includes a first light-diffusing structure 31a. In some embodiments, such as the exemplary embodiments shown in FIG. 2, FIG. 6, and FIG. 7, a first edge L1 is located at the side, facing the midpoint of the first light-emitting unit 11 of the light-shielding structure 21 in the first direction X. The first edge L1 is an edge in the side wall of the first groove portion 3010 adjacent to the light-emitting layer 10. As shown in FIG. 2, FIG. 6, and FIG. 7, the side wall of the first groove portion 3010 includes an upper edge and a lower edge, and the lower edge is closer to the light-emitting layer 10 than the upper edge. Therefore, the lower edge of the side wall of the first groove portion 3010 shown in FIG. 2, FIG. 6, and FIG. 7 is the first edge L1. In some embodiments, since the first edge L1 is located at the side, facing the midpoint of the first light-emitting unit 11, of the light-shielding structure 21, at least part of the first light-diffusing structure 31a is closer to the first light-emitting unit 11 than the light-shielding structure 21 in the first direction X; and at least part of an orthographic projection of the side wall of the second groove portion 3030 on the light-emitting layer 10 is located at the side, facing the first light-emitting unit 11, of the orthographic projection of the light-shielding structure 21 on the light-emitting layer 10. Therefore, the shielding effect of the light-shielding structure 21 on the first color light L1X emitted by the first light-emitting unit 11 at a wide viewing angle in the first direction X is reduced. Furthermore, the probability that the first color light emitted by the first light-emitting unit 11 is shielded and absorbed by the light-shielding structure 21 is significantly reduced during the transmission to the position with a large viewing angle in the first direction X. Finally, at least part of the first color light is received by the side wall of the first groove portion 3010. Therefore, it can be ensured that at least part of the first color light L1X is captured and modulated by the first light-diffusing structure 31a of the first light control unit 31.

In some embodiments, the side wall of the first groove portion 3010 may be a vertically aligned structure as shown in FIG. 2, FIG. 6, and FIG. 7. That is, the side wall of the first groove portion 3010 is parallel to the direction perpendicular to the plane of the display panel 01.

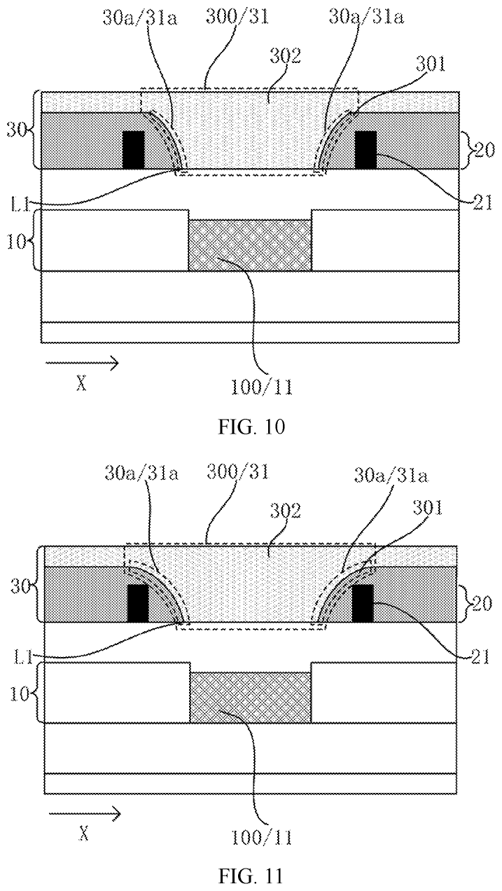

FIG. 10 is a schematic cross-sectional diagram of a first light-emitting unit along a first direction. FIG. 11 is a schematic cross-sectional diagram of a first light-emitting unit along a first direction.

In some embodiments, the first groove portion 3010 is a structure with a narrow lower part and a wide upper part. According to the exemplary embodiments shown in FIG. 10 and FIG. 11, an edge of the side wall of the first groove portion 3010 adjacent to the light-emitting layer 10 is closer to a center of the first light-emitting unit 11 than an edge of the side wall of the first groove portion 3010 away from the light-emitting layer 10. For example, the lower edge in the side wall of the first groove portion 3010 may be adjacent to the light-emitting layer 10 and the upper edge in the side wall of the first groove portion 3010 may be away from the light-emitting layer 10, and the lower edge of the first groove portion 3010 may be closer to the center of the first light-emitting unit 11 than the upper edge thereof.

In some embodiments, the first light control unit 31 includes a first light-diffusing structure 31a. In some embodiments, as shown in FIG. 2, FIG. 6, FIG. 7, and FIG. 10, along the first direction X, the side wall of the first groove portion 3010 of the first light control unit 31 is located at the side, facing the midpoint of the first light-emitting unit 11, of the light-shielding structure 21 of a periphery of the first light-emitting unit 11. When the first groove portion 3010 has a structure with a narrow lower part and a wide upper part, as shown in FIG. 10, an edge (lower edge, i.e., the first edge L1) adjacent to the light-emitting layer 10 in the side wall of the first groove portion 3010 is located at the side, facing the first light-emitting unit 11, of the light-shielding structure 21 in the first direction X. Furthermore, an edge (upper edge) away from the light-emitting layer 10 in the side wall of the first groove portion 3010 is also located at the side, facing the first light-emitting unit 11, of the light-shielding structure 21 in the first direction X. An orthographic projection of the side wall of the first groove portion 3010 on the shielding layer is completely located at the inner side of the light-shielding structure 21 facing the first light-emitting unit 11. That is, the light-shielding structure 21 at the periphery of the first light-emitting unit 11 surrounds an orthographic projection of the first light-emitting unit 11 on the shielding layer, and also surrounds an orthographic projection of the first groove portion 3010 on the shielding layer. Therefore, the first light-diffusing structure 31a of the first light control unit 31 is located at the side of the light-shielding structure 21 facing the first light-emitting unit 11 in the first direction X. In this embodiment, the probability that the first color light L1X emitted by the first light-emitting unit 11 propagating at a wide viewing angle in the first direction X is shielded and absorbed by the light-shielding structure 21 is further reduced. Additionally, the amount of the light received by the side wall of the first groove portion 3010 is increased. Therefore, it can be ensured that more first color light is be captured and modulated by the first light-diffusing structure 31a.

In some embodiments, the first groove portion 3010 is a structure with a narrow lower part and a wide upper part. In some embodiments, as shown in FIG. 11, an edge (lower edge, i.e., the first edge L1) adjacent to the light-emitting layer 10 in the side wall of the first groove portion 3010 is located at the side of the light-shielding structure 21 facing the first light-emitting unit 11 in the first direction X, and an edge (upper edge) away from the light-emitting layer 10 in the side wall of the first groove portion 3010 is overlapped with the first light-emitting unit 11 in the direction perpendicular to the plane of the display panel 01, or is located at the side of the light-shielding structure 21 away from the first light-emitting unit 11 in the first direction X. A portion of an orthographic projection of the side wall of the first groove portion 3010 on the shielding layer may be located at an inner side of the light-shielding structure 21 facing the first light-emitting unit 11. Therefore, a portion of the first light-diffusing structure 31a of the first light control unit 31 may be located at the side of the light-shielding structure 21 facing the first light-emitting unit 11 in the first direction X. In this embodiment, the first light-diffusing structure 31a can capture a relatively greater amount of the first color light. In addition, in this embodiment, it can be avoided as much as possible that a distance between the light-shielding structure 21 and the first light-emitting unit 11 in the first direction X increase due to the arrangement of the side wall of the first groove portion 3010, thereby avoiding affecting the resolution design of the display panel 01.

In some embodiments, the first light control unit 31 includes the first light-diffusing structure 31a. In some embodiments, as shown in the exemplary embodiments depicted in FIG. 2, FIG. 6, FIG. 7, FIG. 10, and FIG. 11, the first edge L1 is located between the light-shielding structure 21 and the first light-emitting unit 11 in the first direction X. In this embodiment, the side wall of the first groove portion 3010 in the first light control unit 31 may not be overlapped with the first light-emitting unit 11 in the direction perpendicular to the plane of the display panel 01. The first light control unit 31 is prevented from affecting the first color light at a front viewing angle, so as to ensure that the first color light is normally emitted at the front viewing angle as much as possible.

FIG. 12 is a schematic cross-sectional diagram of a first light-emitting unit along a first direction.

In some embodiments, the first light control unit 31 includes the first light-diffusing structure 31a. In some embodiments, as shown in FIG. 12, the first edge L1 is partially overlapped with the first light-emitting unit 11 in the direction perpendicular to the plane of the display panel 01. Therefore, the side wall of the first groove portion 3010 in the first light control unit 31 is partially overlapped with the first light-emitting unit 11 in the direction perpendicular to the plane of the display panel 01. Then, the first light-diffusing structure 31a can receive more first color light and modulate the light. In addition, when at least part of the side wall of the first groove portion 3010 is located at the side of the light-shielding structure 21 facing the first light-emitting unit 11, a distance between the light-shielding structure 21 and the first light-emitting unit 11 in the first direction X does not need to be too large, which is beneficial to achieving high resolution of the display panel.

It should be noted that, although the first groove portion 3010 illustrated in FIG. 12 is a structure with a narrow lower part and a wide upper part, the technical solution may also be applicable to the situation in which the side wall of the first groove portion 3010 is parallel to the direction perpendicular to the plane of the display panel 01. It should also be noted that, although the upper edge of the side wall of the first groove portion 3010 illustrated in FIG. 12 is overlapped with the light-shielding structure 21 in the direction perpendicular to the plane of the display panel 01, the technical solution may also be applicable to the situation in which the upper edge of the side wall of the first groove portion 3010 is located at the side of the light-shielding structure 21 facing the first light-emitting unit 11 in the first direction X. Furthermore, this may also be applicable to the situation in which the upper edge of the side wall of the first groove portion 3010 is located at the side of the light-shielding structure 21 away from the first light-emitting unit 11 in the first direction X.

In some embodiments, the first light control unit 31 includes the first light-converging structure 31b. In some embodiments, as shown in FIG. 8 and FIG. 9, the second edge L2 is located at the side of the light-shielding structure 21 facing the midpoint of the first light-emitting unit 11 in the second direction Y. The second edge L2 is an edge of the side wall of the second groove portion 3030 adjacent to the light-emitting layer 10. As shown in FIG. 8 and FIG. 9, the side wall of the second groove portion 3030 includes an upper edge and a lower edge, and the lower edge is closer to the light-emitting layer 10 than the upper edge. Therefore, the lower edge of the side wall of the second groove portion 3030 shown in FIG. 8 and FIG. 9 is the second edge L2. In the embodiment, since the second edge L2 is located at the side of the light-shielding structure 21 facing the midpoint of the first light-emitting unit 11, at least part of the first light-converging structure 31b is closer to the first light-emitting unit 11 than the light-shielding structure 21 in the second direction Y. Additionally, at least part of an orthographic projection of the side wall of the second groove portion 3030 on the light-emitting layer 10 is located at a side, facing the first light-emitting unit 11, of an orthographic projection of the light-shielding structure 21 on the light-emitting layer 10. Therefore, the shielding effect of the light-shielding structure 21 on the first color light L1Y emitted by the first light-emitting unit 11 at a wide viewing angle in the second direction Y is reduced, the probability that the first color light emitted by the first light-emitting unit 11 is shielded and absorbed by the light-shielding structure 21 in the transmission process to the position with a wide viewing angle in the second direction Y is significantly reduced, and at least part of the first color light is received by the side wall of the second groove portion 3030. Therefore, it can be ensured that at least part of the first color light L1Y is captured and modulated by the first light-converging structure 31b of the first light control unit 31.

In some embodiments, the side wall of the second groove portion 3030 may be a vertically aligned structure as shown in FIG. 8 and FIG. 9. That is, the side wall of the second groove portion 3030 is parallel to the direction perpendicular to the plane of the display panel 01.

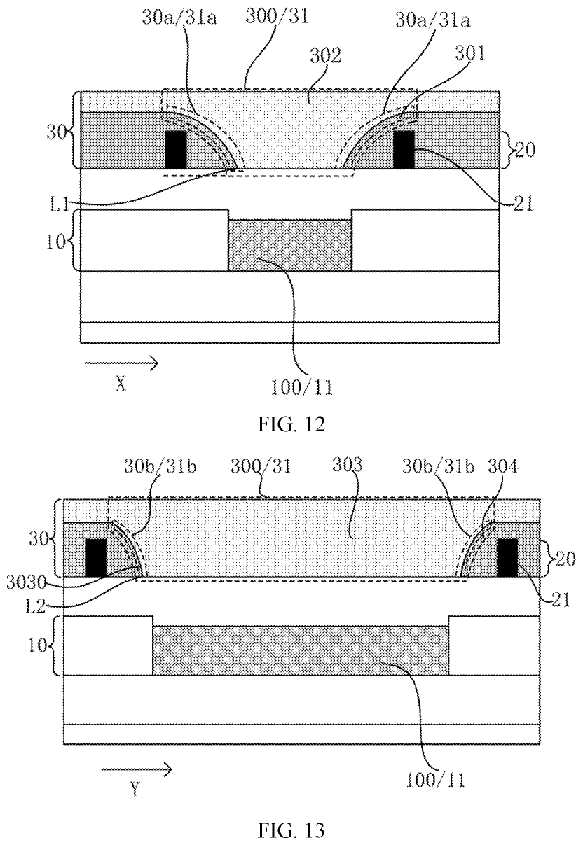

FIG. 13 is a schematic cross-sectional diagram of a second light-emitting unit along a second direction. FIG. 14 is a schematic cross-sectional diagram of a second light-emitting unit along a second direction.

In some embodiments, the second groove portion 3030 may be a structure with a narrow lower part and a wide upper part. According to the embodiments shown in FIG. 13 and FIG. 14, an edge of the side wall of the second groove portion 3030 adjacent to the light-emitting layer 10 is closer to a center of the first light-emitting unit 11 than an edge of the side wall of the second groove portion 3030 away from the light-emitting layer 10. For example, in FIG. 13 and FIG. 14, the lower edge in the side wall of the second groove portion 3030 is adjacent to the light-emitting layer 10 and the upper edge is away from the light-emitting layer 10, and the lower edge of the second groove portion 3030 is closer to the center of the first light-emitting unit 11 than the upper edge.

In some embodiments, the first light control unit 31 includes the first light-converging structure 31b. In some embodiments, such as the embodiments shown in FIG. 8, FIG. 9, and FIG. 13, along the second direction Y, the side wall of the second groove portion 3030 of the first light control unit 31 is located at a side, facing the midpoint of the first light-emitting unit 11, of the light-shielding structure 21 of a periphery of the first light-emitting unit 11. When the second groove portion 3030 has a structure with a narrow lower part and a wide upper part, as shown in FIG. 13, an edge (lower edge, i.e., the second edge L2) adjacent to the light-emitting layer 10 in the side wall of the second groove portion 3030 is located at the side of the light-shielding structure 21 facing the first light-emitting unit 11 in the second direction Y, and an edge (upper edge) away from the light-emitting layer 10 in the side wall of the second groove portion 3030 is also located at the side of the light-shielding structure 21 facing the first light-emitting unit 11 in the second direction Y. An orthographic projection of the side wall of the second groove portion 3030 on the shielding layer is completely located at the inner side of the light-shielding structure 21 facing the first light-emitting unit 11. That is, the light-shielding structure 21 at the periphery of the first light-emitting unit 11 surrounds an orthographic projection of the first light-emitting unit 11 on the shielding layer and also surrounds an orthographic projection of the second groove portion 3030 on the shielding layer. Therefore, the first light-converging structure 31b of the first light control unit 31 is located at the side of the light-shielding structure 21 facing the first light-emitting unit 11 in the second direction Y. In this embodiment, the probability that the first color light L1Y emitted by the first light-emitting unit 11 propagating at a wide viewing angle in the second direction Y is shielded and absorbed by the light-shielding structure 21 is further reduced, and the amount of light received by the side wall of the second groove portion 3030 is increased. Therefore, it can be ensured that more first color light can be captured and modulated by the first light-converging structure 31b.

In some embodiments, the second groove portion 3030 is a structure with a narrow lower part and a wide upper part. In some embodiments, as shown in FIG. 14, an edge (lower edge, or the second edge L2) adjacent to the light-emitting layer 10 in the side wall of the second groove portion 3030 is located at the side of the light-shielding structure 21 facing the first light-emitting unit 11 in the second direction Y. Furthermore, an edge (upper edge) away from the light-emitting layer 10 in the side wall of the second groove portion 3030 is overlapped with the first light-emitting unit 11 in the direction perpendicular to the plane of the display panel 01, or is located at the side of the light-shielding structure 21 away from the first light-emitting unit 11 in the second direction Y. A portion of an orthographic projection of the side wall of the first groove portion 3030 on the shielding layer is located at an inner side of the light-shielding structure 21 facing the first light-emitting unit 11. Therefore, a portion of the first light-converging structure 31b of the first light control unit 31 is located at the side of the light-shielding structure 21 facing the first light-emitting unit 11 in the second direction Y. In this embodiment, the first light-converging structure 31b can capture a relatively greater amount of the first color light. In addition, in this embodiment, it can be avoided as much as possible that a distance between the light-shielding structure 21 and the first light-emitting unit 11 in the second direction X due to the arrangement of the side wall of the second groove portion 3030 increases, thereby avoiding affecting the resolution design of the display panel 01.

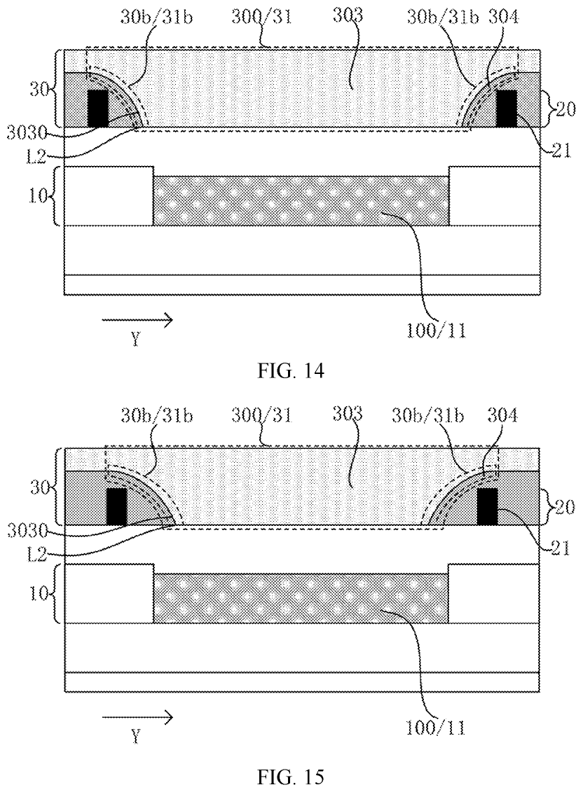

FIG. 15 is a schematic cross-sectional diagram of a second light-emitting unit along a second direction.

In some embodiments, the first light control unit 31 includes the first light-converging structure 31b. In some embodiments, such as the exemplary embodiment shown in FIG. 15, the second edge L2 is overlapped with the first light-emitting unit 11 in the direction perpendicular to the plane of the display panel 01. Therefore, the side wall of the second groove portion 3030 in the first light control unit 31 is partially overlapped with the first light-emitting unit 11 in the direction perpendicular to the plane of the display panel 01. Then, the first light-converging structure 31b can receive more first color light and modulate the light. In addition, when at least part of the side wall of the second groove portion 3030 is located at the side of the light-shielding structure 21 facing the first light-emitting unit 11, a distance between the light-shielding structure 21 and the first light-emitting unit 11 in the second direction X does not need to be too large, which is beneficial to achieving high resolution of the display panel 01.

In some embodiments, a length of the first light-emitting unit 11 in the second direction Y is relatively large. As a result, although the two edges of the first light-emitting unit 11 arranged in the second direction Y are covered by the side wall of the second groove portion 3030 in the direction perpendicular to the plane of the display panel 01, the first light-converging structure 31b has less influence on the total light emitted by the first light-emitting unit 11. In some embodiments, the first light control unit 31 includes both the first light-diffusing structure 31a and the first light-converging structure 31b, the first edge L1 is located between the light-shielding structure 21 and the first light-emitting unit 11 in the first direction X, and the second edge L2 is overlapped with the first light-emitting unit 11 in the direction perpendicular to the plane of the display panel 01.

It should be noted that, although the second groove portion 3030 illustrated in FIG. 15 is a structure with a narrow lower part and a wide upper part, the technical solution may also be applicable to the case where the side wall of the second groove portion 3030 is parallel to the direction perpendicular to the plane of the display panel 01. It should also be noted that, although the upper edge of the side wall of the second groove portion 3030 illustrated in FIG. 15 is overlapped with the light-shielding structure 21 in the direction perpendicular to the plane of the display panel 01, the technical solution may also be applicable to the situation in which the upper edge of the side wall of the second groove portion 3030 is located at the side of the light-shielding structure 21 facing the first light-emitting unit 11 in the second direction Y, and may also be applicable to the situation in which the upper edge of the side wall of the second groove portion 3030 is located at the side of the light-shielding structure 21 away from the first light emitting unit 11 in the second direction Y.

As described above, in embodiments where the first light control unit 31 includes the first light-diffusing structure 31a, in order to perform scattering modulation on the light propagating at a wide viewing angle in the first direction X, the first light-diffusing structure 31a extends along the second direction Y, and the first light-diffusing structure 31a is formed mainly depending on the side wall of the first groove portion 3010. Therefore, as shown in FIG. 1 and FIG. 5, at least a portion of the side wall of the first groove portion 3010 extends along the second direction Y. “Extends along the second direction Y” herein means extending substantially along the second direction Y or extending entirely along the second direction Y, and does not mean that the side wall of the first groove portion 3010 have to extend along a straight line.

In some embodiments, an extension direction of the side wall of the first groove portion 3010 of the first light control unit 31 is parallel to an extension direction of edges of the first light-emitting unit 11 opposite to each other in the first direction X. That is, the side wall included in the first groove portion 3010 of the first light control unit 31 has the same extension direction as the edges of the first light-emitting unit 11 opposite to each other in the first direction X. Therefore, the first groove portion 3010 does not affect the light at a wide viewing angle in the second direction Y. In addition, in this embodiment, the area of the first structure 301 can be minimized, so as to minimize the loss generated when the light is refracted and reflected multiple times in the film layers with different refractive indexes.

As described above, when the first light control unit 31 includes the first light-converging structure 31b, in order to modulate the light propagating in the second direction Y at a wide viewing angle, the first light-converging structure 31b extends along the first direction X, and the first light-converging structure 31b is formed mainly depending on the side wall of the second groove portion 3030. Therefore, as shown in FIG. 4 and FIG. 5, at least part of the side wall of the second groove portion 3030 extends along the first direction X. “Extends along the first direction X” herein means extending generally along the first direction X or extending entirely along the first direction X, and does not mean that the side wall of the second groove portion 3030 have to extend along a straight line.

In some embodiments, an extension direction of the side wall of the second groove portion 3030 of the first light control unit 31 is parallel to an extension direction of an edge of the first light-emitting unit 11 opposite the second direction Y. That is, the side wall of the second groove portion 3030 of the first light control unit 31 has the same extension direction as the edges of the first light-emitting unit 11 opposite to each other in the second direction Y. Therefore, the second groove portion 3030 does not affect the light at a wide viewing angle in the first direction X. In addition, in this embodiment, the area of the third structure 303 can be minimized, so as to minimize the loss generated when the light is refracted and reflected multiple times in the film layers with different refractive indexes.

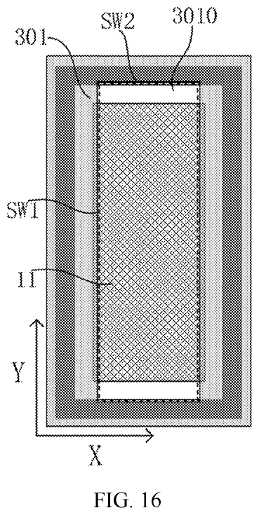

FIG. 16 is a schematic diagram of a projection of a first light-emitting unit.

In some embodiments, such as the exemplary embodiment shown in FIG. 16, when the first light control unit 31 includes the first light-diffusing structure 31a, the first groove portion 3010 of the first light control unit 31 includes first side walls SW1 opposite to each other along the first direction X and second side walls SW2 opposite to each other along the second direction Y. That is, the side wall of the first groove portion 3010 may surround the first light-emitting unit 11. The side wall of the first groove portion 3010 may be a continuous structure. A distance between the second side wall SW2 and the first light-emitting unit 11 in the second direction Y is greater than a distance between the first side wall SW1 and the first light-emitting unit 11 in the first direction X. That is, the second side wall SW2 of the first groove portion 3010 located at the side of the first light-emitting unit 11 in the second direction Y is further away from the first light-emitting unit 11, so as to minimize the influence of the first light-diffusing structure 31a on the first color light emitted by the first light-emitting unit 11 at a wide viewing angle in the second direction Y. In addition, the first groove portion 3010 may be obtained by conventional exposure, development and etching processes, which has no special requirements on the shape of the mask and the positive and negative polarities of the photoresist, and thus is easier to implement.

In some embodiments, as shown in FIG. 16, the second side wall SW2 is overlapped with the light-shielding structure 21 in the direction perpendicular to the plane of the display panel 01, and the first side wall SW2 is not overlapped with the light-shielding structure 21 in the direction perpendicular to the plane of the display panel 01. That is, the second side wall SW2 is closer to the light-shielding structure 21 and the first side wall SW1 is closer to the first light-emitting unit 11, thereby further reducing the influence of the first light-diffusing structure 31a on the first color light emitted by the first light-emitting unit 11 at a wide viewing angle in the second direction Y.

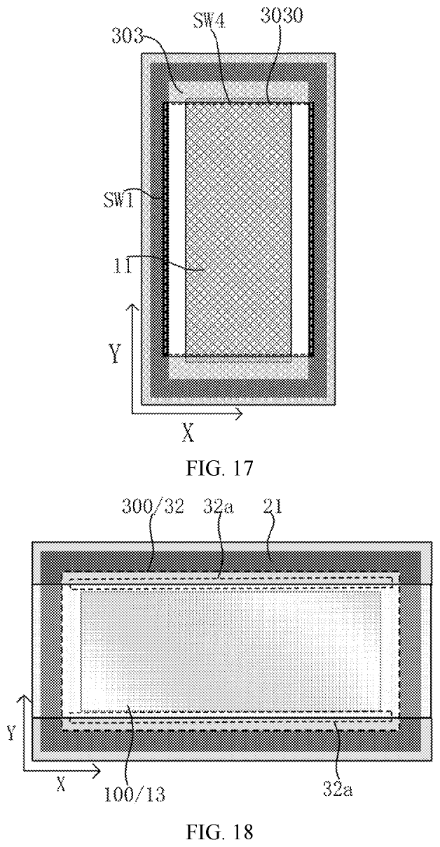

FIG. 17 is a schematic diagram of a projection of a first light-emitting unit.

In some embodiments, such as the exemplary embodiment shown in FIG. 17, when the first light control unit 31 includes the first light-converging structure 31b, the second groove portion 3030 of the first light control unit 31 includes third side walls SW3 opposite to each other along the first direction X and fourth side walls SW4 opposite to each other along the second direction Y. That is, the side wall of the second groove portion 3030 may surround the first light-emitting unit 11. The side wall of the second groove portion 3030 may be a continuous structure. A distance between the third side wall SW3 and the first light-emitting unit 11 in the first direction X is greater than a distance between the fourth side wall SW4 and the first light-emitting unit 11 in the second direction Y. That is, the third side wall SW3 located at the side of the first light-emitting unit 11 in the first direction X in the second groove portion 3030 is further away from the first light-emitting unit 11, so as to minimize the influence of the first light-converging structure 31b on the first color light emitted by the first light-emitting unit 11 at a wide viewing angle in the first direction X. In addition, the second groove portion 3030 may be obtained by conventional exposure, development and etching processes, which has no special requirements on the shape of the mask and the positive and negative polarities of the photoresist, and thus is easier to implement.

In some embodiments, such as the exemplary embodiment shown in FIG. 17, the fourth side wall SW4 is overlapped with the light-shielding structure 21 in the direction perpendicular to the plane of the display panel 01, and the third side wall SW3 is not overlapped with the light-shielding structure 21 in the direction perpendicular to the plane of the display panel 01. That is, the third side wall SW3 is closer to the light-shielding structure 21 and the fourth side wall SW4 is closer to the first light-emitting unit 11, thereby further reducing the influence of the first light-converging structure 31b on the first color light emitted by the first light-emitting unit 11 at a wide viewing angle in the first direction X.

As described above, the difference between the light amount emitted by the first light-emitting unit 11 at a wide viewing angle in the first direction X and the light amount emitted by the first light-emitting unit 11 at a wide viewing angle in the second direction Y is relatively significant for the reasons including the significant difference between the widths of the first light-emitting unit 11 in the two directions. Whereas, if there is no significant difference between the widths of the light-emitting unit 100 in different directions, this problem is not significant. Therefore, there is probably no light control unit 300 provided above the light-emitting unit 100.

As shown in FIG. 1, the light-emitting layer 10 further includes a second light-emitting unit 12. A ratio of a width of the second light-emitting unit 12 along the second direction Y to a width of the second light-emitting unit 12 along the first direction X is a2, a ratio of a width of the first light-emitting unit 11 along the second direction Y to a width of the first light-emitting unit 11 along the first direction X is a1, and |a2−1|<|a1−1|. That is, compared to the first light-emitting unit 11, there is no significant difference between the width of the second light-emitting unit 12 along the second direction Y and the width of the second light-emitting unit 12 along the first direction X. In some embodiments of the present disclosure, in the direction perpendicular to the plane of the display panel 01, the second light-emitting unit 12 is not overlapped with the light control unit 300. That is, there is probably no light control unit 300 provided above the second light-emitting unit 12. The light control layer 30 has a simple structure, which is easy to implement, and there is no significant between the brightness of the second light-emitting unit 12 at a wide viewing angle in the first direction X and the brightness of the second light-emitting unit 12 at a wide viewing angle in the second direction Y.

The technical problems to be solved by the embodiments of the present disclosure include that the light amount of the first color light in the first direction X has different attenuation degrees at wide viewing angles in different directions of the first light-emitting unit 11, thereby resulting in color shift after the first color light is at least mixed with the second color light, which is the light emitted by the second light-emitting unit 12, at wide viewing angles in different directions. In this embodiment, there is no light control unit 300 provided above the second light-emitting unit 12, so that the light amount of the second color light at a wide viewing angle in different directions is not adjusted by the light control unit 300. Therefore, the adjustment solution for the first color light is determined by using the brightness of the second light-emitting unit 12 as a criterion, so as to obtain an ideal specific structure of the first light control unit 31 easier.

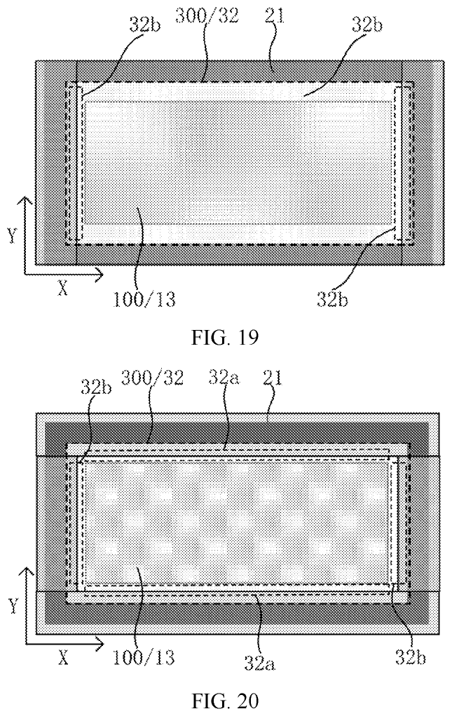

FIG. 18 is a schematic diagram of a projection of a third light-emitting unit. FIG. 19 is a schematic diagram of a projection of a third light-emitting unit. FIG. 20 is a schematic diagram of a projection of a third light-emitting unit.

In some embodiments, the light-emitting layer 10 further includes a third light-emitting unit 13, and a width of the third light-emitting unit 13 along the first direction X is different from a width of the third light-emitting unit 13 along the second direction Y. For example, as shown in FIG. 1 and FIG. 18 to FIG. 20, the width of the third light-emitting unit 13 along the first direction X is greater than the width of the third light-emitting unit 13 along the second direction Y. Since the light-shielding structure 21 is located at the periphery of the light-emitting unit 100, in the light-shielding structure 21 at a periphery of the second light-emitting unit 12, a length of a portion extending along the first direction X is different from a length of a portion extending along the second direction Y. The shielding of the first color light by the light-shielding structure 21 causes different attenuation amount of the first color light in different directions, thereby resulting in color shift. Therefore, the shielding of the third color light, which is the light emitted by the third light-emitting unit 13, by the light-shielding structure 21 will also cause such a problem. It should be noted that, in the embodiments illustrated in FIG. 1 and FIG. 18 to FIG. 20, the width of the third light-emitting unit 13 along the first direction X is greater than the width of the third light-emitting unit 13 along the second direction Y. In some embodiments, the width of the third light-emitting unit 13 along the first direction X may also be less than the width of the third light-emitting unit 13 along the second direction Y.

In some embodiments, such as the exemplary embodiments shown in FIG. 18 to FIG. 20, the plurality of light control units 300 include a second light control unit 32, and the second light control unit 32 is overlapped with the second light-emitting unit 12 in the direction perpendicular to the plane of the display panel 01. That is, the second light control unit 32 is configured to adjust a light path of light emitted by the second light-emitting unit 12. The second light control unit 32 includes a second light-diffusing structure 32a and/or a second light-converging structure 32b. As shown in FIG. 18, the second light control unit 32 includes only the second light-diffusing structure 32a. As shown in FIG. 19, the second light control unit 32 includes only the second light-converging structure 32b. As shown in FIG. 20, the first light control unit 31 includes both the second light-diffusing structure 32a and the second light-converging structure 32b.

According to the embodiments shown in FIG. 18 and FIG. 20, an extension direction of the second light-diffusing structure 32a is parallel to one of the first direction X and the second direction Y in which the third light-emitting unit 13 has a greater width. As shown in FIG. 18 and FIG. 20, the width of the third light-emitting unit 13 in the first direction X is greater than the width of the third light-emitting unit 13 in the second direction Y, and the extension direction of the second light-diffusing structure 32a is identical to that of the second direction Y. It can be understood that when the width of the third light-emitting unit 13 in the second direction Y is greater than the width of the third light-emitting unit 13 in the first direction X, the extension direction of the second light-diffusing structure 32a is identical to that of the first direction X. Similar to the function of the first light-diffusing structure 31a, when the second light control unit 32 includes the second light-diffusing structure 32a, the viewing angle range capable of receiving the second color light in a specific direction can be expanded.

According to the embodiments shown in FIG. 19 and FIG. 20, an extension direction of the second light-converging structure 32b is parallel to one of the first direction X and the second direction Y in which the third light-emitting units 13 has a smaller width. According to the embodiments shown in FIG. 19 and FIG. 20, a width of the third light-emitting unit 13 in the second direction Y is less than a width of the third light-emitting unit 13 in the first direction X, and the extension direction of the second light-converging structure 32b is identical to that of the first direction X. It can be understood that when the width of the third light-emitting unit 13 in the first direction X is greater than the width of the third light-emitting unit 13 in the second direction Y, the extension direction of the second light-converging structure 32b is identical to that of the second direction Y. Similar to the function of the first light-converging structure 31b, when the second light control unit 32 includes the second light-converging structure 32b, the viewing angle range capable of receiving the second color light in a specific direction can be narrowed.

It should be noted that the structural composition and position setting of the second light-diffusing structure 32a may be similar to the structural composition and position setting of the first light-diffusing structure 31a, which will not be described herein again in detail. The structural composition and position configuration of the second light-converging structure 32b may be similar to that of the first light-converging structure 31b, which will not be described herein again in detail.

In some embodiments of the present disclosure, a ratio of a width of the first light-emitting unit 11 along the second direction Y to a width of the first light-emitting unit 11 along the first direction X is a1; a ratio of the one of the second direction Y and the first direction X in which the third light-emitting unit 13 has a greater width to the other one of the second direction Y and the first direction X in which the third light-emitting unit 13 has a smaller width is a3; and a3≠a1. That is, the width difference of the third light-emitting unit 13 between the first direction X and the second direction Y is different from that of the first light-emitting unit 11 between the first direction X and the second direction Y. Therefore, when the first light control unit 31 includes the first light-diffusing structure 31a and the second light control unit 32 includes the second light-diffusing structure 32a, the first light-diffusing structure 31a is different from the second light-diffusing structure 32a. Additionally, in some embodiments, when the first light control unit 31 includes the first light-converging structure 31b and the second light control unit 32 includes the second light-converging structure 32b, the first light-converging structure 31b is different from the second light-converging structure 32b.

For example, the relative position between the side wall of the groove portion in the first light-diffusing structure 31a and the first light-emitting unit 11 is different from the relative position between the side wall of the groove portion in the second light-diffusing structure 32a and the third light-diffusing structure 13. For example, the refractive index difference between the groove portion in the first light-diffusing structure 31a and the structure filled in the groove portion is different from the refractive index difference between the groove portion in the second light-diffusing structure 32a and the structure filled in the groove portion.

For example, the relative position between the side wall of the groove portion in the first light-converging structure 31b and the first light-emitting unit 11 is different from the relative position between the side wall of the groove portion in the second light-converging structure 32b and the third light-emitting unit 13. For example, the refractive index difference between the groove portion in the first light-converging structure 31b and the structure filled in the groove portion is different from the refractive index difference between the groove portion in the second light-converging structure 32b and the structure filled in the groove portion.

In some embodiments, the light control unit 300 above the first light-emitting unit 11 and the light control unit 300 above the third light-emitting unit 13 are set to be different, so as to match the design adapting the difference of the light amount of the first color light at different wide viewing angles in different directions and adapting to the difference of the light amount of the second color light at different wide viewing angles in different directions.

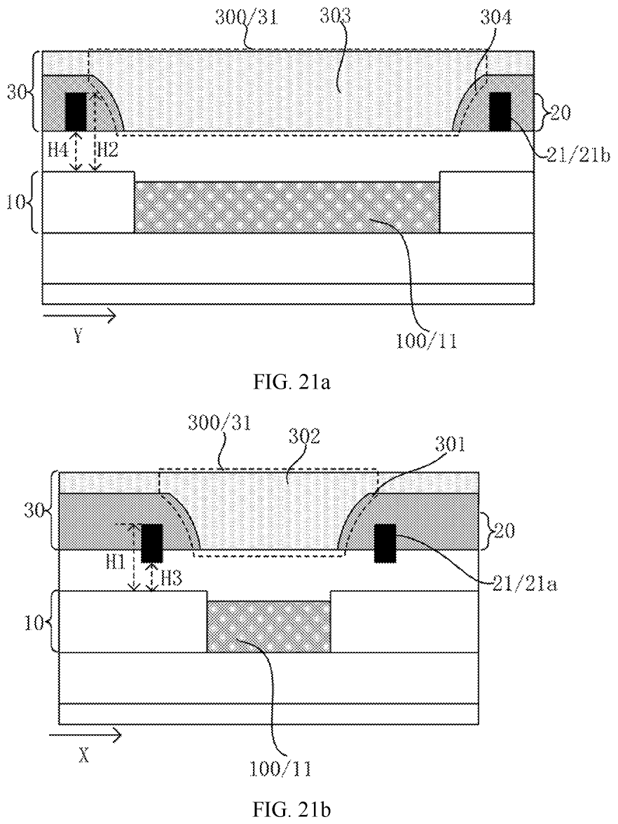

FIG. 21a is a schematic cross-sectional diagram of a first light-emitting unit along a second direction. FIG. 21b is a schematic cross-sectional diagram of a first light-emitting unit along a first direction.

In some embodiments of the present disclosure, with reference to FIG. 21a and FIG. 21b, the light-shielding structure 21 includes a first portion 21a and a second portion 21b, the first portion 21a is adjacent to the first light-emitting unit 11 in the first direction X, and the second portion 21b is adjacent to the first light-emitting unit 11 in the second direction Y. An orthographic projection of the first portion 21a of the light-shielding structure 21 on the light-emitting layer 10 may be adjacently arranged to the first light-emitting unit 11 in the first direction X, and an orthographic projection of the second portion 21b of the light-shielding structure 21 on the light-emitting layer 10 may be adjacently arranged to the first light-emitting unit 11 in the second direction Y.

Along the direction perpendicular to the plane of the display panel 01, a distance between a surface of the first portion 21a away from the light-emitting layer 10 and the light-emitting layer 10 is less than a distance between a surface of the second portion away from the light-emitting layer 10 and the light-emitting layer 10. For example, with continued reference to FIG. 21a and FIG. 21b, a distance between a surface of the first portion 21a away from the light-emitting layer 10 and the light-emitting layer 10 in the direction perpendicular to the plane of the display panel 01 is H1, a distance between a surface of the second portion 21b away from the light-emitting layer 10 and the light-emitting layer 10 in the direction perpendicular to the plane of the display panel 01 is H2, and H1 is less than H2. Compared with the surface of the first portion 21a away from the light-emitting layer 10, the surface of the second portion 21b away from the light-emitting layer 10 is further away from the light-emitting layer 10. Therefore, the second portion 21b has the improved light-shielding effect on the first color light L1Y at a wide viewing angle and exerts a relatively significant light-converging effect on the first color light L1Y emitted to the second direction Y at a wide viewing angle. Compared with the surface of the second portion 21b away from the light-emitting layer 10, the surface of the first portion 21a away from the light-emitting layer 10 is closer to the light-emitting layer 10. Therefore, the first portion 21a has a limited light-shielding effect on light at large angles, so as to minimize the light-shielding effect of the light-shielding structure 21 on the first color light L1X emitted to the first direction X at wide viewing angle.

In some embodiments, a distance between the first portion 21a and the light-emitting layer 10 in the direction perpendicular to the plane where the display panel 01 located is less than a distance between the second portion 21b and the light-emitting layer 10 in the direction perpendicular to the plane of the display panel 01. For example, with reference with FIG. 21a and FIG. 21b, a distance between the first portion 21a and the light-emitting layer 10 in the direction perpendicular to the plane of the display panel 01 is H3, a distance between the second portion 21b and the light-emitting layer 10 in the direction perpendicular to the plane of the display panel 01 is H4, and H3 <H4. In this embodiment, the position of the first portion 21a and/or the second portion 21b in the direction perpendicular to the plane of the display panel 01 can be adjusted, so as to reduce the visible angle difference of the first color light at the wide viewing angles in the first direction X and the second direction Y, respectively.

In some embodiments, such as the exemplary embodiment shown in FIG. 21b, the first portion 21a may be designed to sink toward the light-emitting layer 10, for example, a groove may be designed on the film layer carrying the light-shielding structure 21, and at least part of the first portion 21a is provided in the groove.

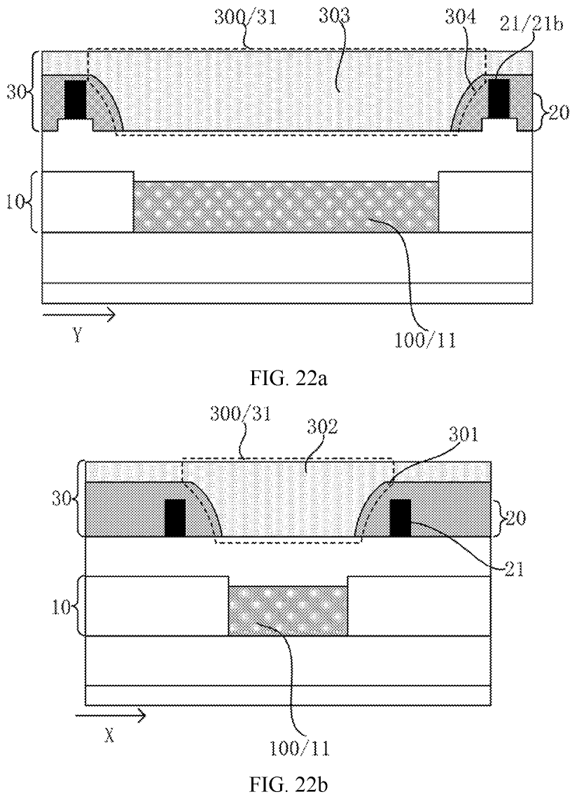

FIG. 22a is a schematic cross-sectional diagram of a first light-emitting unit along a second direction. FIG. 22b is a schematic cross-sectional diagram of a first light-emitting unit along a first direction.

In some embodiments, with reference to FIG. 22a and FIG. 22b, the second portion 21b may be raised towards the direction of the light control layer 30. For example, a protrusion may be formed on the film layer carrying the light-shielding structure 21, and at least part of the second portion 21b is provided on the protrusion.

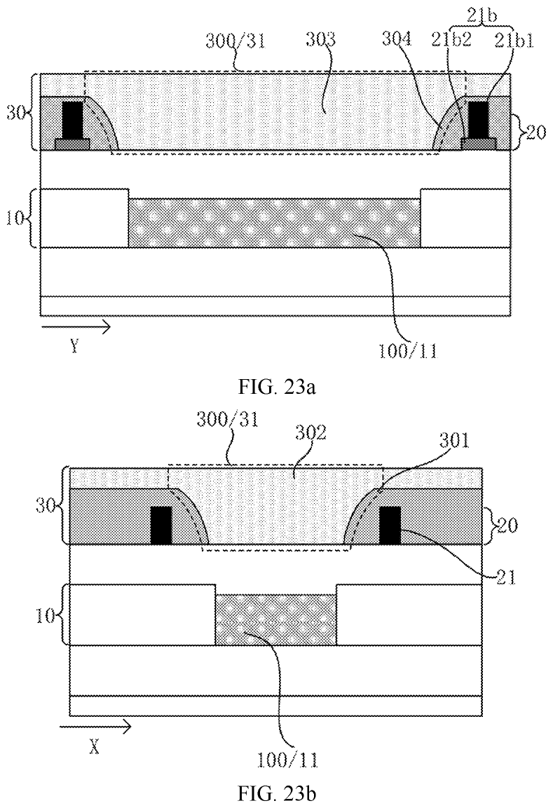

FIG. 23a is a schematic cross-sectional diagram of a first light-emitting unit along a second direction. FIG. 23b is a schematic cross-sectional diagram of a first light-emitting unit along a first direction.

In some embodiments, with reference to FIG. 23a and FIG. 23b, the second portion 21b may include a first sub-portion 21b1 and a second sub-portion 21b2 that are overlapped with each other in the direction perpendicular to the plane of the display panel 01, and the first sub-portion 21b1 and the second sub-portion 21b2 are located in different film layers. In this embodiment, the height of the second portion 21b is increased by increasing the number of film layers of the second portion 21b, thereby increasing a distance between the surface of the second portion 21b away from the light-emitting layer 10 and the first light-emitting unit 11 in the direction perpendicular to the plane of the display panel 01.

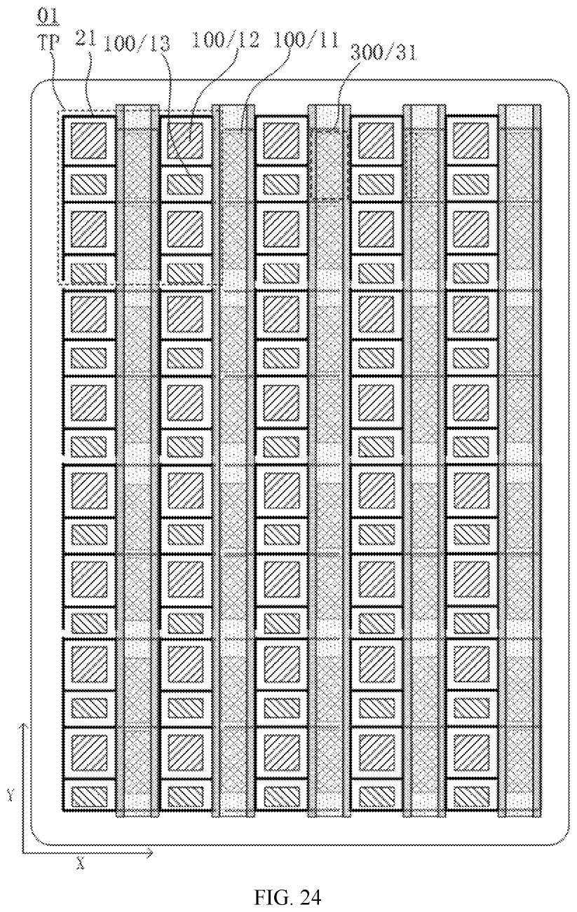

FIG. 24 is a schematic diagram of a display panel according to an embodiment provided in the present disclosure.

In some embodiments of the present disclosure, such as the exemplary embodiment shown in FIG. 24, the display panel 01 includes a mesh touch electrode TP. The touch electrode TP may include interconnected conductive lines, and the conductive lines are provided at positions between regions where the light-emitting units 100 are located. Therefore, the conductive line in the touch electrode TP may be used as the light-shielding structure 21. That is, the light-shielding structure 21 is reused as at least part of the touch electrode TP. In the embodiments of the present disclosure, the problem of color shift at part of viewing angles caused by the inclusion of the mesh touch electrode TP in the display panel 01 can be solved.

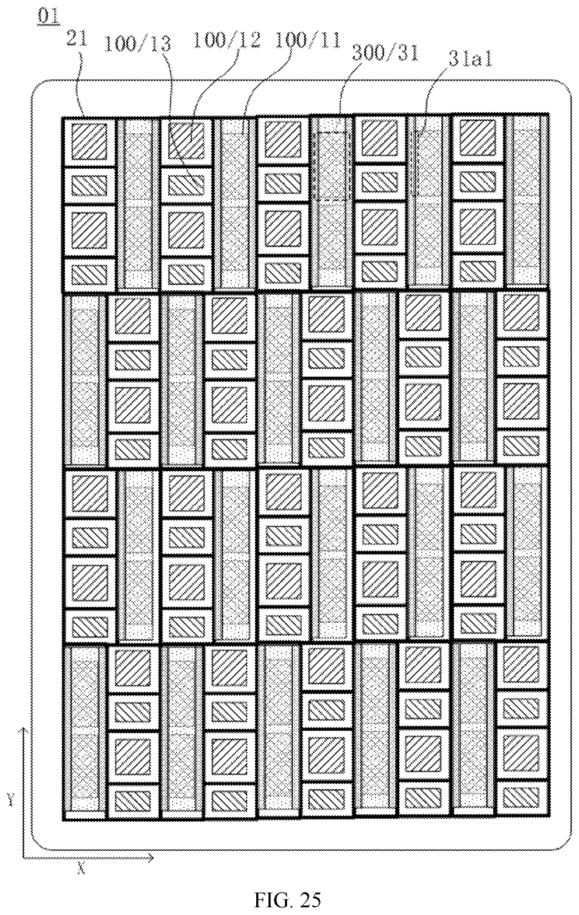

FIG. 25 is a schematic diagram of a display panel provided by an embodiment of the present disclosure.

In some embodiments of the present disclosure, as shown in FIG. 1, FIG. 24 and FIG. 25, along the direction perpendicular to the plane of the display panel, the first light control unit 31 is overlapped with at least two first light-emitting units 11 adjacently arranged along the second direction Y. Therefore, the manufacturing difficulty of the first light control unit 31 can be reduced.

As shown in FIG. 1 and FIG. 24, the first light-emitting units 11 arranged along the second direction Y are sequentially arranged adjacent to each other. That is, the pixel column including the first light-emitting units 11 may include only the first light-emitting units 11. In this case, one first light control unit 31 can be overlapped with each of the first light-emitting units 11 in the pixel column simultaneously. When the first light control unit 31 includes the first light-diffusing structure 31a, the first groove portion 3010 in the first light-diffusing structure 31a may be overlapped with each of the first light-emitting units 11 in the pixel column, and the manufacturing difficulty and process precision requirements of the first groove portion 3010 are reduced.

As shown in FIG. 25, each pixel column may include the first light-emitting unit 11, two first light-emitting units 11 are used as a first unit group, each pixel column may include a first unit group, and one first light control unit 31 may be overlapped with each first light-emitting unit 11 in the first unit group simultaneously.

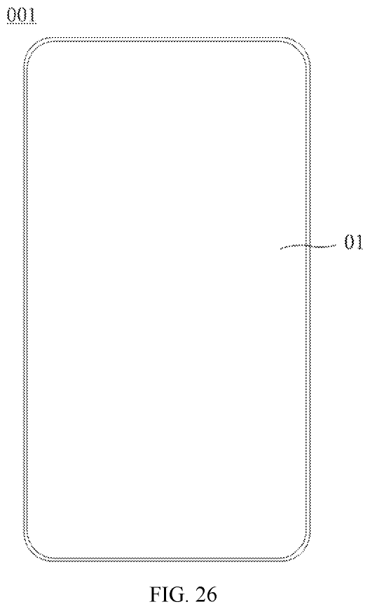

FIG. 26 is a schematic diagram of a display device provided by an embodiment of the present disclosure.

According to the exemplary embodiment shown in FIG. 26, an embodiment of the present disclosure further provides a display device 001, including the display panel 01 according to any of the above embodiments. It should be understood that the display device 001 shown in FIG. 26 is merely illustrative, and the display device 001 may be any electronic device having a display function, such as a mobile phone, a tablet computer, a notebook computer, an e-book, a television, and a splicing display device.

The above description merely illustrates preferred embodiments of the present disclosure and are not intended to limit the present disclosure. It should be noted that any modification, equivalent substitution, improvement, and the like made within the spirit and principle of the present disclosure shall fall within the scope of the present disclosure.

What is claimed is:

1. A display panel, comprising:
a light-emitting layer comprising a plurality of light-emitting units, wherein the plurality of light-emitting units comprise a first light-emitting unit, a width of the first light-emitting unit along a first direction is smaller than a width of the first light-emitting unit along a second direction, the first direction intersects with the second direction, and the first direction and the second direction are parallel to a plane of the display panel;
a shielding layer located at a side of the light-emitting layer facing a light-emitting surface of the display panel, wherein the shielding layer comprises a light-shielding structure, and the light-shielding structure is located at a periphery of at least one of the light-emitting units; and
a light control layer located at a side of the shielding layer away from the light-emitting layer, wherein the light control layer comprises a plurality of light control units;
wherein the plurality of light control units comprise a first light control unit that is overlapped with the first light-emitting unit in a direction perpendicular to the plane of the display panel; and
wherein the first light control unit comprises at least one of a first light-diffusing structure that extends along the second direction, and a first light-converging structure, that extends along the first direction.

2. The display panel according to claim 1, wherein a ratio of a width of the first light-emitting unit along the second direction to a width of the first light-emitting unit along the first direction is a1;
wherein the light-emitting layer further comprises a second light-emitting unit, and a ratio of a width of the second light-emitting unit in the second direction to a width of the second light-emitting unit in the first direction is a2, wherein |a2−1|<|a1−1|; and
wherein the second light-emitting unit is not overlapped with the light control units along the direction perpendicular to the plane of the display panel.

3. The display panel according to claim 1, wherein the light-emitting layer further comprises a third light-emitting unit; and a width of the third light-emitting unit along the first direction is different from a width of the third light-emitting unit along the second direction;
the plurality of light control units comprise a second light control unit, the second light control unit is overlapped with the second light-emitting unit in the direction perpendicular to the plane of the display panel; and
the second light control unit comprises a second light-diffusing structure and/or a second light-converging structure, an extension direction of the second light-diffusing structure is parallel to one of the first direction and the second direction in which the third light-emitting unit has a greater width, and an extension direction of the second light-converging structure is parallel to one of the first direction and the second direction in which the third light-emitting unit has a smaller width.

4. The display panel according to claim 3, wherein a ratio of a width of the first light-emitting unit along the second direction to a width of a first light-emitting unit along the first direction is a1, and a ratio of one of the first direction and the second direction in which the third light-emitting unit has a greater width to one of the first direction and the second direction in which the third light-emitting unit has a smaller width is a3, wherein a3≠a1; and wherein the first light-diffusing structure is different from the second light-diffusing structure, and/or the first light-converging structure is different from the second light-converging structure.

5. The display panel according to claim 1, wherein at least one of the light control units comprises a first structure and a second structure, a refractive index of the first structure is greater than a refractive index of the second structure, the first structure comprises a first groove portion, at least part of the second structure is filled in the first groove portion, and the first groove portion is overlapped with the light-emitting unit in the direction perpendicular to the plane of the display panel; and
wherein a first edge is located at a side, facing a midpoint of the first light-emitting unit, of the light-shielding structure in the first direction; and the first edge is an edge, adjacent to the light-emitting layer, of a side wall of the first groove portion.

6. The display panel according to claim 5, wherein along the first direction, a side wall of a first groove portion of the first light control unit is located at a side, facing the midpoint of the first light-emitting unit, of the light-shielding structure located at a periphery of the first light-emitting unit.

7. The display panel according to claim 5, wherein the first edge is located between the light-shielding structure and the first light-emitting unit in the first direction.

8. The display panel according to claim 5, wherein an extension direction of a side wall of a first groove portion of the first light control unit is parallel to an extension direction of an edge of the first light-emitting unit opposite to the first direction.

9. The display panel according to claim 5, wherein a first groove portion of the first light control unit comprises a first side wall opposite the first direction and a second side wall opposite the second direction; and
wherein a distance between the second side wall and the first light-emitting unit in the second direction is greater than a distance between the first side wall and the first light-emitting unit in the first direction.

10. The display panel according to claim 9, wherein the second side wall is overlapped with the light-shielding structure in the direction perpendicular to the plane of the display panel, and the first side wall is not overlapped with the light-shielding structure in the direction perpendicular to the plane of the display panel.

11. The display panel according to claim 1, wherein at least one of the light control units comprises a third structure and a fourth structure, a refractive index of the third structure is less than a refractive index of the fourth structure, the third structure comprises a second groove portion, at least part of the fourth structure is filled in the second groove portion, and the second groove portion is overlapped with the light-emitting unit in the direction perpendicular to the plane of the display panel; and
wherein a second edge is located at a side, facing a midpoint of the first light-emitting unit, of the light-shielding structure in the second direction, and the second edge is an edge, adjacent to the light-emitting layer, of a side wall of the second groove portion.

12. The display panel according to claim 11, wherein along the second direction, a side wall of a second groove portion of the first light control unit is located at the side, facing the midpoint of the first light-emitting unit, of the light-shielding structure located at a periphery of the first light-emitting unit.

13. The display panel according to claim 11, wherein the second edge is overlapped with the first light-emitting unit in the direction perpendicular to the plane of the display panel.

14. The display panel according to claim 11, wherein an extension direction of a side wall of a second groove portion of the first light control unit is parallel to an extension direction of an edge of the first light-emitting unit opposite to the second direction.

15. The display panel according to claim 11, wherein a second groove portion of the first light control unit comprises a third side wall opposite to the first direction and a fourth side wall opposite to the second direction; and
wherein a distance between the third side wall and the first light-emitting unit in the first direction is greater than a distance between the fourth side wall and the first light-emitting unit in the second direction.

16. The display panel according to claim 15, wherein the fourth side wall is overlapped with the light-shielding structure in the direction perpendicular to the plane of the display panel, and the third side wall is not overlapped with the light-shielding structure in the direction perpendicular to the plane of the display panel.

17. The display panel according to claim 1, wherein the light-shielding structure comprises a first portion and a second portion, the first portion is adjacent to the first light-emitting unit in the first direction, and the second portion is adjacent to the first light-emitting unit in the second direction; and
wherein along the direction perpendicular to the plane of the display panel, a distance between a surface of the first portion away from the light-emitting layer and the light-emitting layer is less than a distance between a surface of the second portion away from the light-emitting layer and the light-emitting layer.

18. The display panel according to claim 17, wherein a distance between the first portion and the light-emitting layer in the direction perpendicular to the plane of the display panel is less than a distance between the second portion and the light-emitting layer in a direction perpendicular to the plane of the display panel.

19. The display panel according to claim 17, wherein the second portion comprises a first sub-portion and a second sub-portion that are overlapped with each other in the direction perpendicular to the plane of the display panel, and the first sub-portion and the second sub-portion are located in different film layers.

20. The display panel according to claim 1, wherein along the direction perpendicular to the plane of the display panel, the first light control unit is overlapped with at least two first light-emitting units adjacently arranged along the second direction.

21. The display panel according to claim 1, wherein the display panel comprises a mesh touch electrode, and the light-shielding structure is reused as at least part of the touch electrode.

22. A display device, comprising a display panel,
wherein the display panel comprises:
a light-emitting layer comprising a plurality of light-emitting units, wherein the plurality of light-emitting units comprise a first light-emitting unit, a width of the first light-emitting unit along a first direction is smaller than a width of the first light-emitting unit along a second direction, the first direction intersects with the second direction, and the first direction and the second direction are parallel to a plane of the display panel;
a shielding layer located at a side of the light-emitting layer facing a light-emitting surface of the display panel, wherein the shielding layer comprises a light-shielding structure, the light-shielding structure is located at a periphery of at least one of the light-emitting units; and
a light control layer located at a side of the shielding layer away from the light-emitting layer, wherein the light control layer comprises a plurality of light control units;
wherein the plurality of light control units comprise a first light control unit that is overlapped with the first light-emitting unit in a direction perpendicular to the plane of the display panel; and
wherein the first light control unit comprises at least one of a first light-diffusing structure that extends along the second direction, and a first light-converging structure that extends along the first direction.
